(19) United States
(12) Patent Application Publication
(10) Pub. No.: US 2013/0244351 A1
(43) Pub. Date: Sep. 19, 2013

(54) METHOD OF INSPECTING SEMICONDUCTOR DEVICE, METHOD OF FABRICATING SEMICONDUCTOR DEVICE, AND INSPECTION TOOL

(71) Applicant: KABUSHIKI KAISHA TOSHIBA, Tokyo (JP)

(72) Inventors: Daisuke YAMASHITA, Ishikawa-ken (JP); Hironobu SHIBATA, Hyogo-ken (JP); Akira EZAKI, Hyogo-ken (JP)

(73) Assignee: KABUSHIKI KAISHA TOSHIBA, Tokyo (JP)

(21) Appl. No.: 13/780,641

(22) Filed: Feb. 28, 2013

(30) Foreign Application Priority Data
Mar. 19, 2012 (JP) 2012-061632

(51) Int. Cl. G01R 31/26

(52) U.S. Cl. CPC G01R 31/26; H01L 22/14
USPC 438/17; 324/762.01

(57) ABSTRACT

An aspect of one embodiment, there is provided a method of inspecting a semiconductor device, attaching an inspection tool on a back surface of a semiconductor substrate, the inspection tool including a sheet and a holding frame, the sheet being larger than the semiconductor substrate and being provided an opening in a center portion of the sheet, the opening being smaller than the semiconductor substrate, the holding frame holding an outer periphery of the sheet, a supporting substrate being attached on a front surface of the semiconductor substrate, removing the supporting substrate attached on the front surface of the semiconductor substrate, and inspecting electrical characteristics of the semiconductor substrate.

### FIELD

Embodiments described herein relate to a method of inspecting a semiconductor device, a method of fabricating a semiconductor device, and an inspection tool.

### BACKGROUND

In a vertical semiconductor device such as a discrete semiconductor, an electric current is passed perpendicular to a semiconductor substrate (wafer). Therefore, electrical characteristics of the vertical semiconductor device formed on a wafer needs to be inspected in a state where a probe of an electrical characteristic inspection apparatus is in contact with a front surface electrode disposed at a front surface side of the wafer and a test stage of the electrical characteristic inspection apparatus is in contact with a back surface electrode disposed at a back surface side of the wafer.

In the vertical semiconductor device, generally, the back surface of the wafer is thinned by grinding, polishing, etching or the like, and then various processes are performed on the back surface of the wafer. However, warpage of the thinned wafer is so large in general that the handling of the thinned wafer is difficult. Further, defects may easily occur at the time of conveying or processing the wafer. For example, the wafer may be easily broken or cracked. Therefore, the wafer is enforced by attaching a surface protecting sheet, such as a BSG tape, or a supporting substrate, such as a glass substrate, onto the front surface of the wafer to prevent breaking or cracking of the wafer.

However, in a state where the BSG tape or the glass substrate is attached onto the front surface of the wafer, the probe of the electrical characteristics inspection device cannot be in contact with the front surface electrode. Therefore, it is difficult to inspect the electrical characteristics of the vertical semiconductor device. As a result, it is required to expose the front surface electrode by detaching the BSG tape or the glass substrate attached onto the front surface of the wafer. Usually, the BSG tape or the glass substrate is detached in a state where the wafer is mounted on a dicing sheet. However, after detaching the BSG tape or the glass substrate, the dicing sheet may not be detached in order to maintain the strength of the wafer. Therefore, the test stage cannot be in contact with the back surface electrode and, accordingly, the electrical characteristics of the vertical semiconductor device cannot be inspected.

As a result, it is proposed that a sheet having an opening should be attached on a front surface of the wafer to measure the electrical characteristics after detaching the BSG tape or the glass substrate from the front surface of the wafer. In the proposal, the probe is in contact with the front surface electrode through the opening of the sheet to establish electrical conduction.

However, according to a conventional method described above, for example, since the wafer is supported from the front surface side of the wafer, it is required to detach the BSG tape while the back surface of the wafer is performed to be processed. Further, in the wafer where the BSG tape is detached, the strength of the wafer is not maintained, accordingly, the processing on the back surface of the wafer cannot be performed.

### BRIEF DESCRIPTION OF THE DRAWINGS

FIGS. 1A and 1B are a plan view and a cross-sectional view, respectively, showing a configuration of an inspection tool according to an embodiment.

FIGS. 2A and 2B are a cross-sectional view and a plan view, respectively, showing a production apparatus of the inspection tool according to an embodiment.

FIGS. 3A to 3F are cross-sectional views showing processing steps of fabricating an inspection tool according to the embodiment.

FIGS. 4A to 4E are cross-sectional views showing processing steps of fabricating a semiconductor device according to the embodiment.

FIGS. 5A to 5C are cross-sectional views showing processing steps of fabricating a semiconductor device according to a modification of the embodiment.

### DETAILED DESCRIPTION

An aspect of one embodiment, there is provided a method of inspecting a semiconductor device, including attaching an inspection tool on a back surface of a semiconductor substrate, the inspection tool including a sheet and a holding frame, the sheet being larger than the semiconductor substrate and being provided an opening in a center portion of the sheet, the opening being smaller than the semiconductor substrate, the holding frame holding an outer periphery of the sheet, a supporting substrate being attached on a front surface of the semiconductor substrate, removing the supporting substrate attached on the front surface of the semiconductor substrate, and inspecting electrical characteristics of the semiconductor substrate.

An aspect of another embodiment, there is provided a method of fabricating a semiconductor device, including attaching an inspection tool on a back surface of a semiconductor substrate, the inspection tool including a sheet and a holding frame, the sheet being larger than the semiconductor substrate and being provided an opening in a center portion of the sheet, the opening being smaller than the semiconductor substrate, the holding frame holding an outer periphery of the sheet, a supporting substrate being attached on a front surface of the semiconductor substrate, removing the supporting substrate attached on the front surface of the semiconductor substrate, inspecting electrical characteristics of the semiconductor substrate, attaching a dicing sheet on the back surface of the semiconductor substrate, and dicing the semiconductor substrate to produce semiconductor chips, each of the chips including the semiconductor device.

An aspect of another embodiment, there is provided an inspection tool, including a sheet being larger than a semiconductor substrate and being provided an opening in a center portion of the sheet, the opening being smaller than the semiconductor substrate, the sheet being attached on a back surface of the semiconductor substrate, and a holding frame holding an outer periphery of the sheet.

Hereinafter, embodiments will be described in detail with reference to the drawings.

### EMBODIMENT

(Configuration of Inspection Tool)

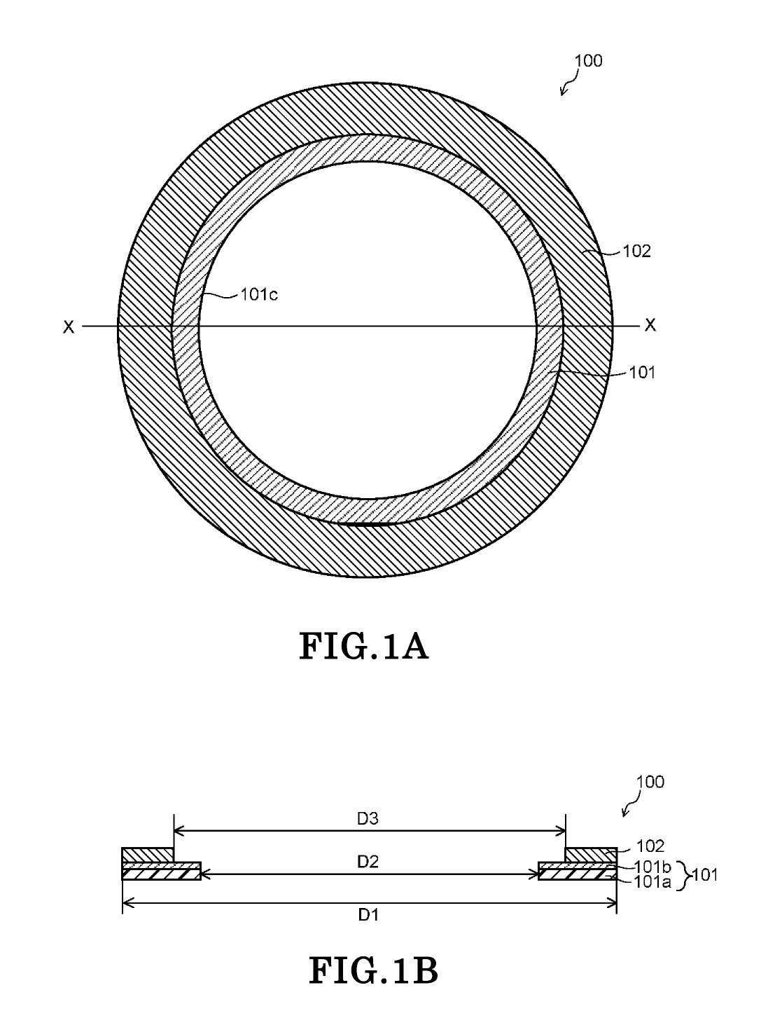

FIGS. 1A and 1B are configuration views showing an inspection tool according to an embodiment. FIG. 1A is a plan view showing the inspection tool. FIG. 1B is a cross-sectional view showing an inspection tool taken along the line X-X of FIG. 1A.

The inspection tool 100 includes a sheet 101 and a metal frame 102. The sheet 101 is a dicing sheet. The sheet 101 includes a sheet base material 101a and an adhesive layer 101b. The adhesive layer 101b is provided on one surface of the sheet base material 101a. The sheet base material 101a is formed of an elastic resin material, such as PVC (polyvinyl chloride) or PET (polyethylene terephthalate).

The sheet 101 is a circular sheet having a circular opening 101c at a center portion. A diameter D1 of the sheet 101 is longer than a diameter of a semiconductor substrate W (hereinafter, referred to as a wafer W) to be inspected. A diameter D2 (inner diameter of the sheet 101) of the opening 101c is approximately 6 mm shorter than the diameter of the wafer W. Further, any one of an ultraviolet curable sheet, a non-ultraviolet curable sheet, and a heat resistant sheet can be used as the sheet 101.

The metal frame 102 is a ring-shaped holding frame (for example, dicing frame) which holds an outer periphery of the sheet 101. An inner diameter D3 of the metal frame 102 is longer than the diameter of the wafer W. A material of the metal frame 102 is aluminum or stainless steel, for example. Further, materials other than a metal may be used after establishing strength required to convey the wafer W attached on the sheet 101.

(Inspection Tool Production Apparatus 100)

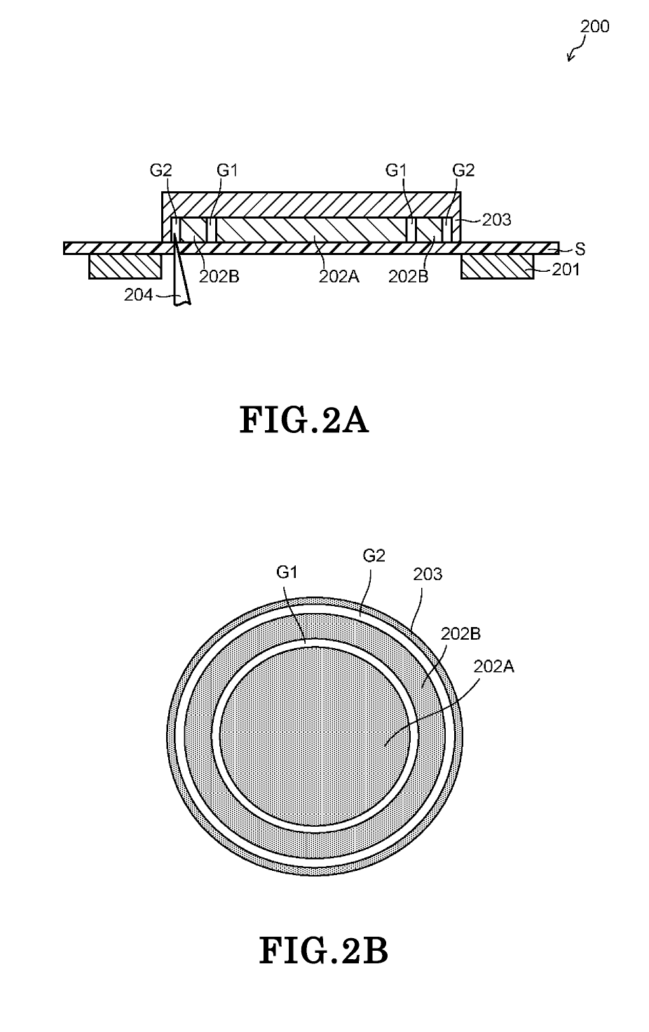

FIGS. 2A and 2B are configuration views showing a production apparatus for fabricating the sheet 101. FIG. 2A is a cross-sectional view showing the production apparatus. FIG. 2B is a plan view showing an adsorption stage and a handler (conveying arm). Hereinafter, a configuration of the production apparatus will be described with reference to FIGS. 2A and 2B.

The manufacturing device 200 includes a cut stage 201, an adsorption stage 202, a handler 203, and a cutter 204.

The cut stage 201 is a circular frame to attach the above-mentioned dicing sheet (hereinafter, referred to as a sheet S). The adsorption stage 202 includes an inner peripheral adsorption unit 202A with a porous state and an outer peripheral adsorption unit 202B formed by sintering particulate metal or ceramic.

An undercut G1 of the cutter 204 is provided between the inner peripheral adsorption unit 202A and the outer peripheral adsorption unit 202B. The inner peripheral adsorption unit 202A and the outer peripheral adsorption unit 202B are connected to a vacuum processing mechanism (for example, a dry pump) which is not shown. The adsorption stage 202 adsorbs the sheet attached on the cut stage 201.

The handler 203 conveys the adsorption stage 202. An undercut G2 of the cutter 204 is provided between the handler 203 and the outer peripheral adsorption unit 202B. The cutter 204 cuts the sheet S adsorbed on the adsorption stage 202 along the undercuts G1, G2.

As shown in FIG. 2B, each of the inner peripheral adsorption unit 202A, the outer peripheral adsorption unit 202B, and the handler 203 has a circular shape and concentrically disposed. Therefore, when the sheet S is cut along the undercuts G1, G2 by the cutter 204, the sheet S has a shape of the sheet 101 described with reference to FIG. 1.

(Processing Steps of the Inspection Tool 100)

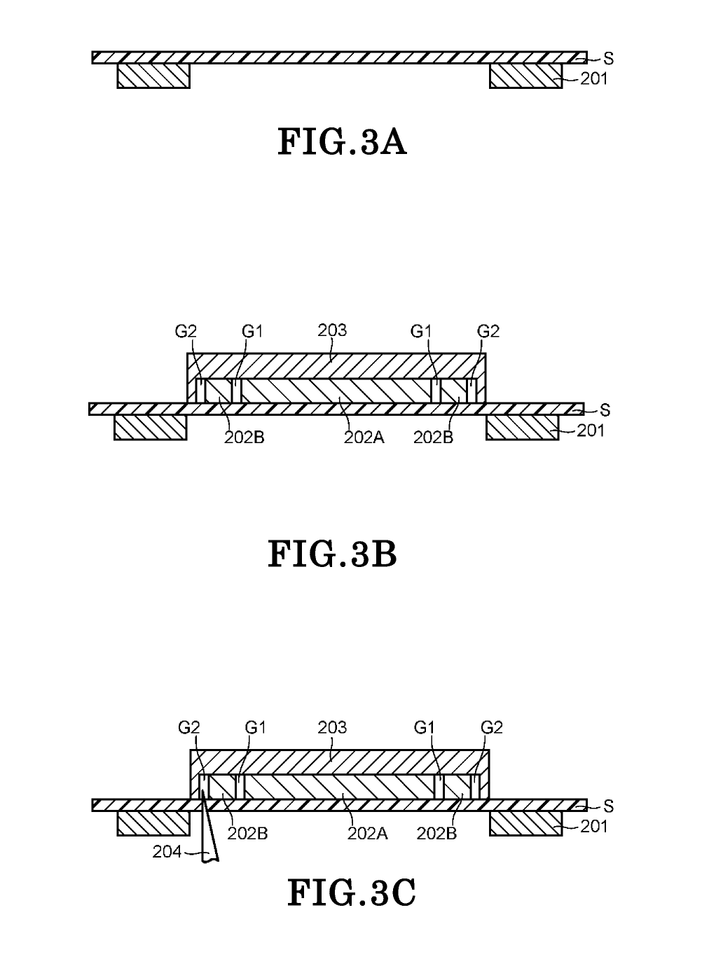

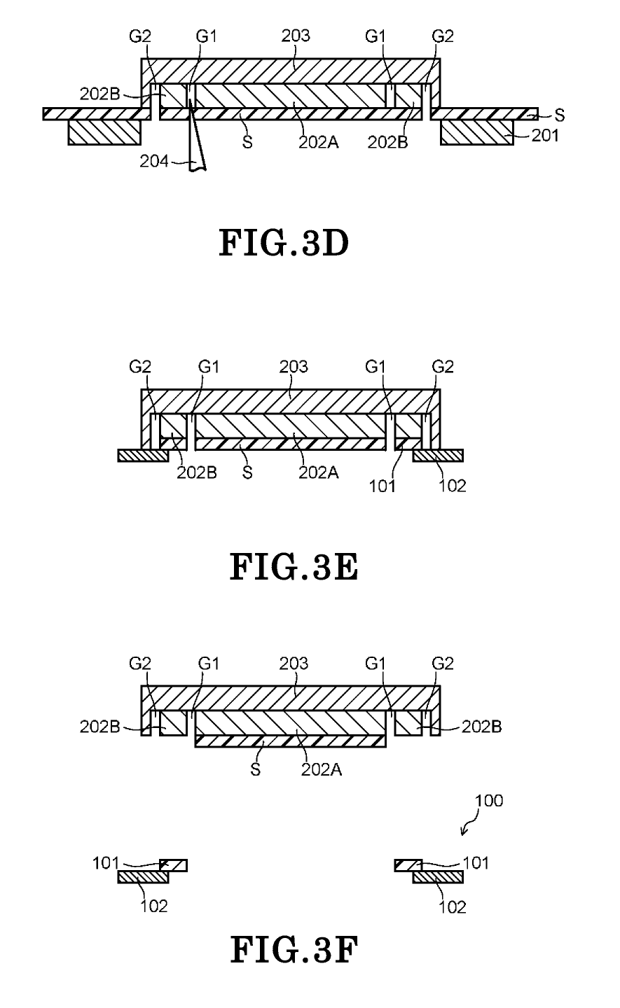

FIGS. 3A to 3F are cross-sectional views showing processing steps of fabricating an inspection tool according to an embodiment. Hereinafter, a method of fabricating the inspection tool 100 will be described with reference to the drawings.

As shown in FIG. 3A, the sheet S is drawn out while the adhesive surface of the sheet S faces the lower side (cut stage side), and the adhesive surface of the sheet S is attached on the cut stage 201.

As shown in FIG. 3B, the handler 203 is moved to bring an adsorbed face of the adsorption stage 202 into contact with a side of the sheet S which is opposite to the cut stage 201. Next, the sheet S is adsorbed to the inner peripheral adsorption unit 202A and the outer peripheral adsorption unit 202B.

As shown in FIG. 3C, the sheet S is cut along the undercut G2 using the cutter 204. As shown in FIG. 3D, the sheet S is cut along the undercut G1 using the cutter 204. Therefore, the sheet 101 is cut from the sheet S. Further, after cutting the sheet S along the undercut G1, the sheet S can be cut along the undercut G2.

As shown in FIG. 3E, the handler 203 is moved to attach the cut sheet 101 onto the metal frame 102.

As shown in FIG. 3F, after the adsorption of the outer peripheral adsorption unit 202B is released, the handler 203 is moved to retreat the adsorption stage 202.

As described above, the inspection tool 100 having the sheet 101 attached on the metal frame 102 is fabricated by the method described with reference to FIGS. 3A to 3F. Note that, an inspection tool having a slightly smaller outer diameter can be fabricated using a circular sheet S adsorbed on the inner peripheral adsorption unit 202A. For example, after manufacturing an inspection tool for a wafer having a diameter of 300 mm, when an inspection tool for a wafer having a diameter of 200 mm is fabricated using a circular sheet S adsorbed on the inner peripheral adsorption unit 202A, a manufacturing cost for the inspection tool may be reduced. In addition, after manufacturing an inspection tool for a wafer having a diameter of 200 mm, an inspection tool for a wafer having a diameter of 150 mm can be fabricated using a circular sheet S adsorbed on the inner peripheral adsorption unit 202A.

(Fabricating of Semiconductor Device C)

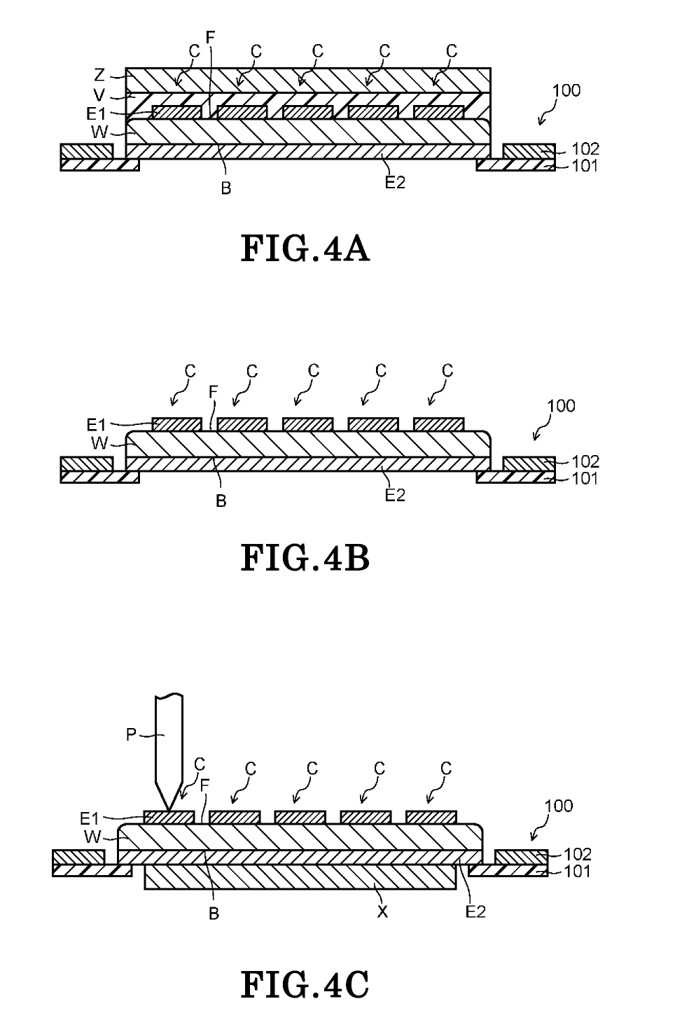

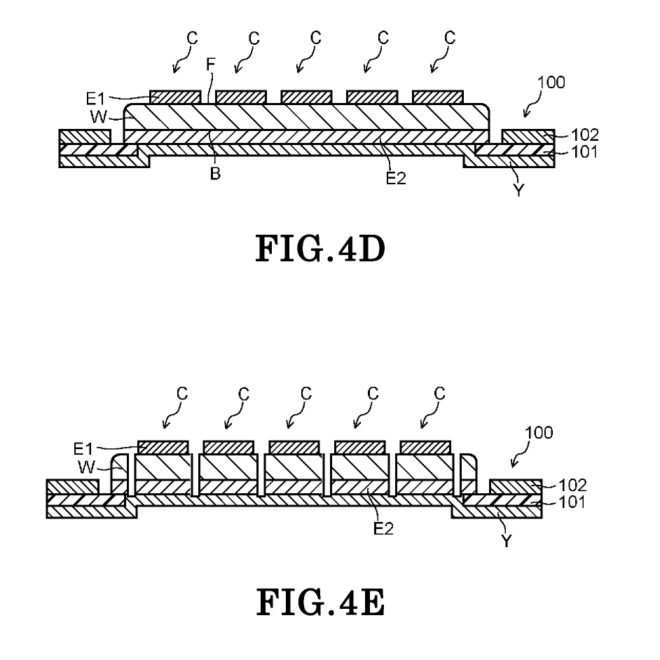

FIGS. 4A to 4E are cross-sectional views showing processing steps of fabricating a semiconductor device C. Hereinafter, a method of fabricating the semiconductor device C will be described with reference to the drawings.

As shown in FIG. 4A, a wafer W having a plurality of semiconductor devices C formed on a front surface F and having a back surface electrode E2 formed on a back surface B is prepared. A supporting substrate Z is bonded to the front surface F of the wafer W using a temporary fixing adhesive agent V. In a necessary state, the supporting substrate Z can be thinned by grinding the substrate Z or by other means. The back surface B of the wafer W is mounted on an adhesive surface side of the sheet 101 of the inspection tool 100. When the wafer W is mounted on the sheet 101, the wafer W is adhered in an air-evacuated state to be under reduced pressure, or a pressure is applied on the supporting substrate Z or from the side of the sheet base material 101a of the sheet 101 using a roller. Further, the adhesion in the air-evacuated state can be performed in conjunction with the pressure application.

As shown in FIG. 4B, the supporting substrate Z is detached from the front surface F of the wafer W. The supporting substrate Z is detached using a separating and cleaning apparatus. After detaching the supporting substrate Z, the front surface F of the wafer W is cleaned and the adhesive agent V is removed from the front surface F of the wafer W.

As shown in FIG. 4C, a probe P of an electrical characteristics inspection device is brought into contact with the front surface electrode E1 of the semiconductor device C formed at the back surface of the wafer W. A test stage X of the electrical characteristics inspection apparatus is brought into contact with the back surface electrode E2 formed on the back surface B of the wafer W which is exposed on the surface of the sheet 101. The electrical characteristics of the semiconductor device C are measured.

As shown in FIG. 4D, after measuring the electrical characteristics, a dicing sheet Y is attached onto the back surface B of the wafer W. The dicing sheet Y is attached by the adhesion in the air-evacuated state to be under the reduced pressure or by applying a pressure on the inspection tool 100 using a roller. Further, the adhesion in the air-evacuated state can be performed in conjunction to the pressure application.

Note that, in the above method, a step corresponding to a thickness of the sheet 101 is formed on the back surface B of the wafer W. However, the dicing sheet Y is conformally adhered when being adhered in the air-evacuated state to minimize the bubbles generated in the step. Accordingly, the influence on the dicing processing quality can be reduced. In addition, for example, the outer periphery of the wafer W is cut using a cutting blade which rotates at high speed to remove the step, and subsequently the dicing process which will be described below can be performed.

As shown in FIG. 4E, the wafer W is diced to produce chips, each including the semiconductor device C. Note that, in the embodiment, the wafer W is fully cut. Alternatively, the wafer W is partly cut and then the dicing sheet Y is extended to produce the chips.

As described above, according to the embodiment, the electrical characteristics in the wafer state is inspected as will be described below. First, an inspection tool 100 is prepared. The inspection tool 100 includes a sheet 101, having a diameter larger than the wafer W and an opening having a diameter smaller than the wafer W formed at the center, and a metal frame 102 that holds the outer periphery of the sheet 101. Next, a semiconductor device C is formed and an inspection tool 100 is attached on a back surface B of a wafer W having a supporting substrate Z attached on a front surface F. The supporting substrate Z is detached from the wafer W and a probe P of electrical characteristics inspection apparatus is brought into contact with a front surface electrode E1 of the semiconductor device C formed on the wafer W. A test stage X of the electrical characteristics inspection device is brought into contact with the back surface electrode E2 formed on the back surface of the wafer W which is exposed on the surface of the sheet 101. The electrical characteristics of the semiconductor device C is inspected by the back surface conduction.

Further, the sheet 101 or the dicing sheet Y is attached in a state adhered in the air-evacuated state to be under the reduced pressure, a state where a pressure is applied on the supporting substrate Z or from the side of the sheet base material 101a of the sheet 101 using a roller, or a state where the adhered state are used in conjunction with the pressure application. Therefore, the adhesiveness of the sheet may be maintained. In addition, the bubbles generated between the sheet 101 and the dicing sheet Y may be minimized.

When the sheet 101 is fabricated, the inspection tool 100 having a slightly smaller outer diameter is fabricated using the circular sheet S which is adsorbed on the inner peripheral adsorption unit 202A. Therefore, the fabrication cost of the inspection tool 100 can be reduced.

Further, when the non-ultraviolet curable sheet is used as the sheet 101, the fabrication cost of the inspection tool 100 can be further reduced since the non-ultraviolet curable sheet is inexpensive. In addition, when the ultraviolet curable sheet, of which adhesiveness is lowered as the ultraviolet ray, is irradiated is used as the sheet 101, the ultraviolet ray can be irradiated after inspecting the electrical characteristics in the wafer state. In this case, since the adhesiveness is lowered, the stress onto the wafer W or paste residue from the sheet 101 on the back surface electrode E2 can be reduced when the sheet 101 is detached. Furthermore, when the heat resistant sheet is used as the sheet 101, the electrical characteristics can be inspected at a high temperature.

### Modification of Embodiment

In the embodiment described above, the dicing sheet Y is attached on the back surface B of the wafer W in a state where the sheet 101 of the inspection tool 100 remains on the back surface B of the wafer W. The modification of the embodiment is described regarding an aspect in which the dicing sheet Y is attached on the back surface of the wafer W after detaching the sheet 101 of the inspection tool 100 from the back surface B of the wafer W.

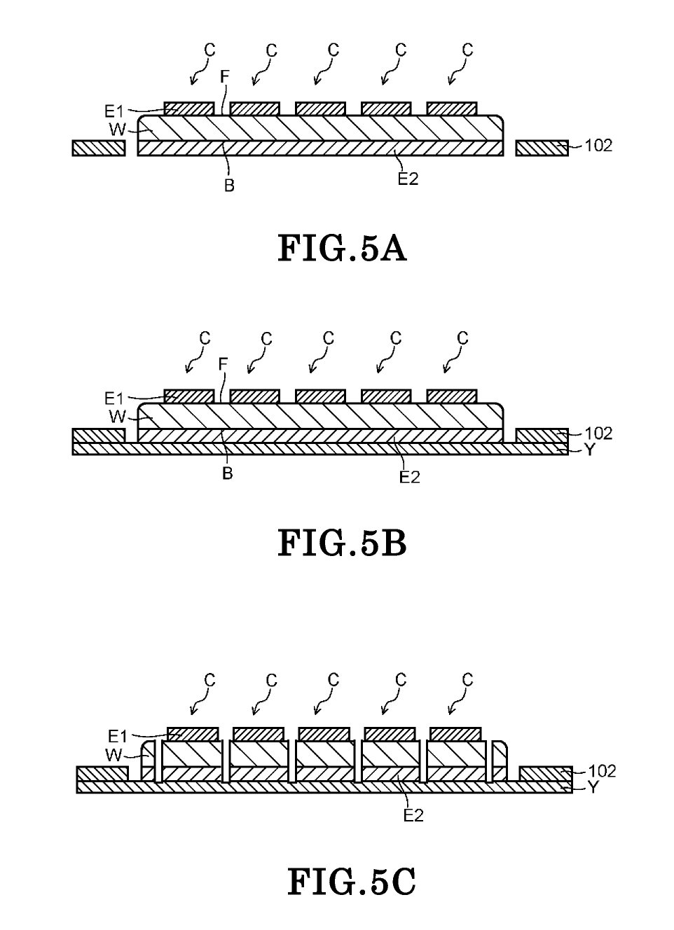

FIGS. 5A to 5C are cross-sectional views showing processing steps of fabricating a semiconductor device C according to the modification of the embodiment. Since the processing steps until the stage shown in FIG. 4C is similar to the processing steps of the semiconductor device C according to the above-described embodiment, the description will not be repeated. In addition, the components which are equal to or similar to the components described with reference to FIGS. 1 to 6 are denoted by the same reference numerals and the description will not be repeated.

As shown in FIG. 5A, the sheet 101 of the inspection tool 100 is detached after measuring the electrical characteristics. When the sheet 101 is detached, the sheet 101 of the inspection tool 100 is detached in a state where the wafer W is adsorbed from the front surface F in order to prevent the damage of the thinned wafer W.

As shown in FIG. 5B, the dicing sheet Y is attached on a back surface B of the wafer W and a back surface of the metal frame 102 of the inspection tool 100. The dicing sheet Y is attached by the adhesion in the air-evacuated state to be under the reduced pressure or by applying a pressure from the dicing sheet Y using a roller. Further, the adhesion in the air-evacuated state can be performed in conjunction with the pressure application to the dicing sheet Y.

As shown in FIG. 5C, the wafer W is diced to produce chips, each including the semiconductor device C. The wafer W is fully cut. However, the dicing sheet Y can be extended to produce the chips after partly cutting the wafer W.

As described above, in the modification, the dicing sheet Y is attached after detaching the sheet 101 attached on the back surface B of the wafer W. Therefore, no step is formed on the dicing sheet Y attached on the back surface B of the wafer W so that processing performance in the dicing of the wafer W can be maintained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of inspecting a semiconductor device, comprising:
attaching an inspection tool on a back surface of a semiconductor substrate, the inspection tool including a sheet and a holding frame, the sheet being larger than the semiconductor substrate and being provided an opening in a center portion of the sheet, the opening being smaller than the semiconductor substrate, the holding frame holding an outer periphery of the sheet, a supporting substrate being attached on a front surface of the semiconductor substrate;
removing the supporting substrate attached on the front surface of the semiconductor substrate; and
inspecting electrical characteristics of the semiconductor substrate.

2. The method of claim 1, wherein
in the inspecting of the electrical characteristics, a probe of an inspection apparatus is brought into contact with the front surface of the semiconductor substrate and a test stage of the inspection apparatus is brought into contact with the back surface exposed at the opening of the semiconductor substrate.

3. The method of claim 1, wherein
attaching the inspection tool on the back surface of the semiconductor substrate is performed in a state under a reduced pressure and/or an applied pressure by a roller.

4. The method of claim 1, wherein
the opening of the inspection tool has a circular shape and a diameter of the opening is 2-6 mm smaller than a diameter of the semiconductor substrate.

5. The method of claim 1, wherein
the sheet has a circular shape.

6. The method of claim 1, wherein
in the attaching of the inspection tool on the back surface of the semiconductor substrate, the inspection tool is tentatively attached on the semiconductor substrate by an adhesive agent, the adhesive agent is removed in the removing the supporting substrate.

7. A method of fabricating a semiconductor device, comprising:
attaching an inspection tool on a back surface of a semiconductor substrate, the inspection tool including a sheet and a holding frame, the sheet being larger than the semiconductor substrate and being provided an opening in a center portion of the sheet, the opening being smaller than the semiconductor substrate, the holding frame holding an outer periphery of the sheet, a supporting substrate being attached on a front surface of the semiconductor substrate;
removing the supporting substrate attached on the front surface of the semiconductor substrate;
inspecting electrical characteristics of the semiconductor substrate;
attaching a dicing sheet on the back surface of the semiconductor substrate; and
dicing the semiconductor substrate to produce semiconductor chips, each of the chips including the semiconductor device.

8. The method of claim 7, wherein
in the inspecting of the electrical characteristics, a probe of an inspection apparatus is brought into contact with the front surface of the semiconductor substrate and a test stage of the inspection apparatus is brought into contact with the back surface exposed from the opening of the semiconductor substrate.

9. The method of claim 7, wherein
attaching the inspection tool on the back surface of the semiconductor substrate is performed in a state under a reduced pressure and/or an applied pressure by a roller.

10. The method of claim 7, wherein
the dicing sheet is attached on the back surface of the semiconductor substrate after the removing of the sheet.

11. The method of claim 7, wherein
the attaching of the sheet on the back surface of the semiconductor substrate is performed in a state under a reduced pressure and/or an applied pressure by a roller.

12. The method of claim 7, wherein
in the attaching of the inspection tool on the back surface of the semiconductor substrate, the inspection tool is tentatively attached on the semiconductor substrate by an adhesive agent, the adhesive agent is removed in the removing the supporting substrate.

13. The method of claim 7, wherein
the sheet is extended to produce the chips after partly cutting the semiconductor substrate in the dicing of the semiconductor substrate.

14. An inspection tool, comprising:
a sheet being larger than a semiconductor substrate and being provided an opening in a center portion of the sheet, the opening being smaller than the semiconductor substrate, the sheet being attached on a back surface of the semiconductor substrate; and
a holding frame holding an outer periphery of the sheet.

15. The inspection tool of claim 14, wherein
the opening has a circular shape and a diameter of the opening is 2-6 mm smaller than a diameter of the semiconductor substrate.

16. The inspection tool of claim 14, wherein
the sheet has a circular shape.

17. The inspection tool of claim 14, wherein
the sheet has a stacked structure in which a base material and an adhesive layer are laminated, the holding frame is provided on the adhesive layer.

18. The inspection tool of claim 14, wherein
the base material is a non-ultraviolet curable type.
